(19) United States
(12) Patent Application Publication
(10) Pub. No.: US 2006/0073275 A1
(43) Pub. Date: Apr. 6, 2006

(54) Process and apparatus for producing single-walled carbon nanotube

(76) Inventors: Shigeo Maruyama, Setagaya-ku (JP); Shohei Chiashi, Setagaya-ku (JP)

Correspondence Address: BIRCH STEWART KOLASCH & BIRCH, PO BOX 747, FALLS CHURCH, VA, 22040-0747, US

(21) Appl. No.: 10/540,826

(22) PCT Filed: Dec. 26, 2003
(86) PCT No.: PCT/JP03/17056

§ 371 Date: Jun. 24, 2005

(30) Foreign Application Priority Data
Dec. 27, 2002 (JP) 2002-382007

(51) Int. Cl. C23C 16/00

(52) U.S. Cl. 427/248.1; 118/715

(57) ABSTRACT

A solution prepared by dissolving an organic metal compound in an organic solvent is sprayed from a pore nozzle into a pre-heating furnace of 50 to 600° C. in a reaction furnace in a rare gas atmosphere of 500 Torr or less by pressurizing with an inert gas; a mixed gas of the organic metal compound and the organic solvent which are pre-heated and vaporized is fed into a main heating furnace which is adjacent to the above pre-heating furnace and heated to 550 to 1000° C. in a rare gas atmosphere of 500 Torr or less; the organic metal compound is thermally decomposed to produce metal fine particles; the organic solvent is thermally decomposed with the above particles being used as a catalyst to produce carbon atoms; and a graphene sheet is grown in a growing part provided at a downstream side of the main heating furnace, whereby a single-walled carbon nanotube is prepared. Ferrocene and iron carbonyl can be used as the organic metal compound, and alcohols and ethers can be used as the organic solvent.

### TECHNICAL FIELD

The present invention relates to a production process for a single-walled carbon nanotube comprising one layer of a graphene sheet and a production apparatus for the same, specifically to a process for producing a single-walled carbon nanotube having a high purity in a high yield by spraying an organic metal compound dissolved in an organic solvent into a reaction furnace of a high temperature and an apparatus for producing the same.

### BACKGROUND ART

A carbon nanotube is a carbon cluster comprising a cylindrically wound graphene sheet in which carbon atoms are disposed in a hexagonal network form and having a cross-sectional diameter of 100 nm or less. In particular, it is reported in many cases that a single-walled carbon nanotube (hereinafter referred to as SWNT) comprising one layer of a graphene sheet is useful as a functional material because of specific electrical and chemical characteristics thereof.

An arc discharge process, a laser ablation process, a high frequency plasma process and a thermal decomposition process are known as a production process for SWNT. In recent years, reported are various measures for the kind of catalysts used in the above production processes and a method for carrying them.

A process that using a carbon electrode and mixed electrode of metal and carbon with a hydrocarbon as a carbon source and mixed gas of helium and hydrogen as a carrier gas is disclosed as a production process for SWNT by arc discharge in Japanese Patent Application Laid-Open No. 197325/1995.

Researchers of Rice University disclose a process in which carbon is vaporized by a conventional laser pulse method of Smalley et al. and metal catalyst fine particles of cobalt and the like are floated in the vicinity of a laser focus, are annealed the resulting carbon cluster staying in a free state at 1000 to 1400° C. and 100 to 800 Torr (Japanese translation of PCT international publication for patent application No. 520615/2001).

A process in which a hydrocarbon gas and a powdery metal catalyst are blown into a high frequency plasma of non-electrode in a rare gas atmosphere is disclosed as a high frequency plasma process in U.S. Pat. No. 2,737,736 gazette.

Further, disclosed in Japanese Patent Application Laid-Open No. 011917/1999 is a process in which a fine particle metal catalyst of cobalt, iron and the like is carried on an oxide film on anode and in which a low pressure low ionized gas plasma is generated by micro wave glow discharge to react carbon with hydrogen.

In any of the processes described above, however, a carbon source is catalytically reacted with a metal catalyst in a space staying in a state substantially close to vacuum in the reaction field, so that the carbon source stochastically collides with the metal catalyst, and a relatively large amount of the metal catalyst is required to an amount of the carbon source. Accordingly, the above catalyst remains in SWNT as an impurity, and the operation of removing this metal results in forming defects on the surface of SWNT having high reactivity.

An object of the present invention is to provide a process for producing a single-walled carbon nanotube containing less impurities such as catalyst metals and having a high purity in a high yield by a vapor deposition technique based on thermochemical decomposition and an apparatus for producing the same.

### DISCLOSURE OF THE INVENTION

A thermochemical decomposition process is a process in which a raw material gas of a carbon source is introduced into a reaction vessel together with a carrier gas and further a metal ultrafine particle catalyst is concurrently introduced thereinto to carry out reaction at 800 to 1200° C., whereby a carbon nanotube is obtained.

FIG. 6 is a drawing showing a schematic diagram of a conventional reaction furnace used for a thermal decomposition process. In this process, metal fine particles of a catalyst which are put on a substrate are placed in the reaction furnace and heated to a reaction temperature, and then a raw material gas and a carrier gas are allowed to pass therethrough to decompose the raw material gas, whereby a carbon nanotube is produced and collected by a filter.

FIG. 2 is a drawing showing the whole diagram of an equipment for carrying out the present invention, and FIG. 1 is a drawing showing a schematic diagram of a reaction furnace.

The present invention relates to a process for producing a single-walled carbon nanotube comprising one layer of a graphene sheet by a vapor deposition technique, wherein a solution prepared by dissolving a catalyst comprising an organic metal compound in an organic solvent is pressurized with an inert gas and then sprayed from a pore nozzle into a pre-heating furnace in a reaction furnace maintained at 50 to 600° C. in a rare gas atmosphere of 500 Torr or less; a mixed gas of the organic solvent and the organic metal compound which are vaporized in the pre-heating furnace is thermally decomposed in a main heating furnace heated at 550 to 1000° C. in a rare gas atmosphere of 500 Torr or less which is close to the above pre-heating furnace; and a graphene sheet is grown in a growing part provided at a downstream side of the main heating furnace, and also the present invention relates to equipment for carrying out the process for producing a single-walled carbon nanotube.

### BRIEF DESCRIPTION OF THE DRAWINGS

FIG. 1 is a drawing showing a schematic diagram of a reaction furnace for SWNT of the present invention.

FIG. 2 is a drawing showing the whole diagram of the production equipment of the present invention.

FIG. 3 is a scanning electron micrograph of SWNT produced in Example 2.

FIG. 4 is a transmission electron micrograph of SWNT produced in Example 2.

FIG. 5 is a Raman spectroscopic spectral chart of SWNT produced in Examples 1 to 3.

FIG. 6 is a drawing showing a schematic diagram of a conventional reaction furnace for SWNT.

FIG. 7 is a scanning electron microphotograph of SWNT produced in Comparative Example 2.

FIG. 8 is a Raman spectroscopic spectral chart of SWNT produced in Comparative Examples 1 to 3.

FIG. 9 is a drawing showing a thermogravimetric analysis result of SWNT produced in the examples and Comparative Example 4.

### BEST MODE FOR CARRYING OUT THE INVENTION

In the present invention, the organic metal compound is decomposed in a reaction furnace to produce metal fine particles, and they act as a catalyst. The above compound includes, metallocenes such as ferrocene, cobaltocene and nickelcene and iron pentacarbonyl (Fe(CO)₅), and ferrocene which is an iron compound is particularly preferred.

The organic solvent is at once a solvent for dissolving the organic metal compound and a raw material for the carbon nanotube. The organic solvent includes alcohols such as ethanol, methanol and propanol, ethers such as dimethyl ether and diethyl ether and ketones.

In the present invention, the organic metal compound is used after dissolved in the organic solvent at a concentration of 0.01 to 1 mass %, preferably 0.05 to 0.2 mass %. If the concentration is less than 0.01 mass %, the effect of the catalyst is not exerted, and if it exceeds 1 mass %, the single-walled carbon nanotube, which is the product is increased in the metal contained in the catalyst. Accordingly, both ranges are not preferred.

An inert gas which can be used in the present invention is preferably rare gases such as helium and argon, and 5 mass % or less of hydrogen may be contained in the inert gas introduced into the reaction furnace.

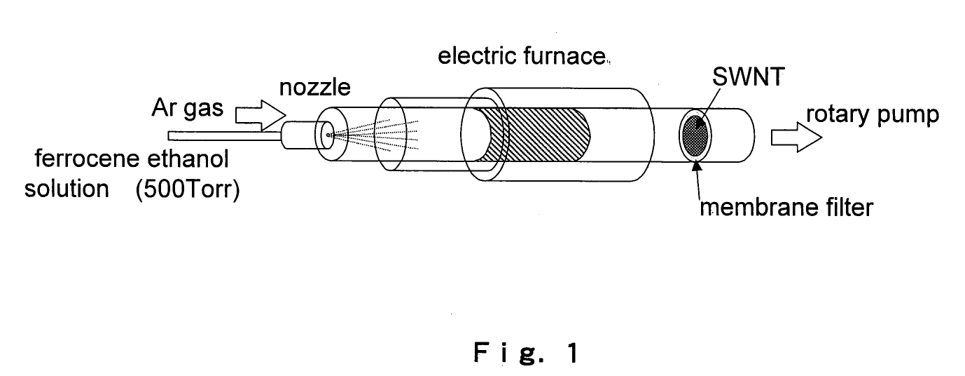

The reaction furnace shown in FIG. 1 comprises a pre-heating part, a main heating part, a growing part and controlling means for heating and maintaining the respective parts at prescribed temperatures. An operation temperature in the pre-heating part is 50 to 600° C., preferably 100 to 400° C., and the organic metal compound and the organic solvent (carbon source) are thermally decomposed at 550 to 1000° C., preferably 700 to 1000° C. in the main heating part. Carbon atoms produced by decomposition of the carbon raw material in the main heating part is annealed in the growing part at a lower temperature than that in the main heating part to grow a graphene sheet.

A nozzle for spraying the solution prepared by dissolving the organic metal compound in the organic solvent has an aperture diameter of 0.01 to 1 mm, and the solution is sprayed into the pre-heating part of the reaction furnace at a back pressure of 100 to 1000 Torr in the form of fine droplets. The reaction furnace is controlled to 1 Torr or less by a rare gas before spraying. The sprayed droplets are heated and vaporized in the pre-heating part. All of the sprayed solution is vaporized, and therefore the vaporized gas is maintained at a fixed mixing ratio of the organic metal compound to the organic solvent. The organic metal compound contained in the vaporized gas is heated and decomposed in the main heating part to produce fine metal particles, and the organic solvent, which is the carbon source is decomposed with the metal particles acting as the catalyst to produce carbon atoms. Then, the carbon atoms are annealed in the growing part to grow a graphene sheet. A carbon nanotube grown by annealing is collected by a membrane filter having a pore diameter of 1 to 20 μm, whereby a single-walled carbon nanotube having a high purity can be obtained in a high yield.

The raw material may be fed to the reaction furnace after evaporating the solution prepared by dissolving the organic metal compound in the organic solvent. In this process, the solution described above does not have to be sprayed into the furnace to vaporize the solution, and therefore it is the most effective process in industrialization. In order to actualize such process, preferably installed are an evaporator for evaporating the solution described above, a feeding system for supplying the evaporated solution into a furnace and a pre-heating part, a main heating part and a growing part each having the same structure described above.

### EXAMPLES

The present invention shall be explained below in further details with reference to examples and comparative examples, but the present invention shall not be restricted to the examples described below.

### Examples 1 to 3

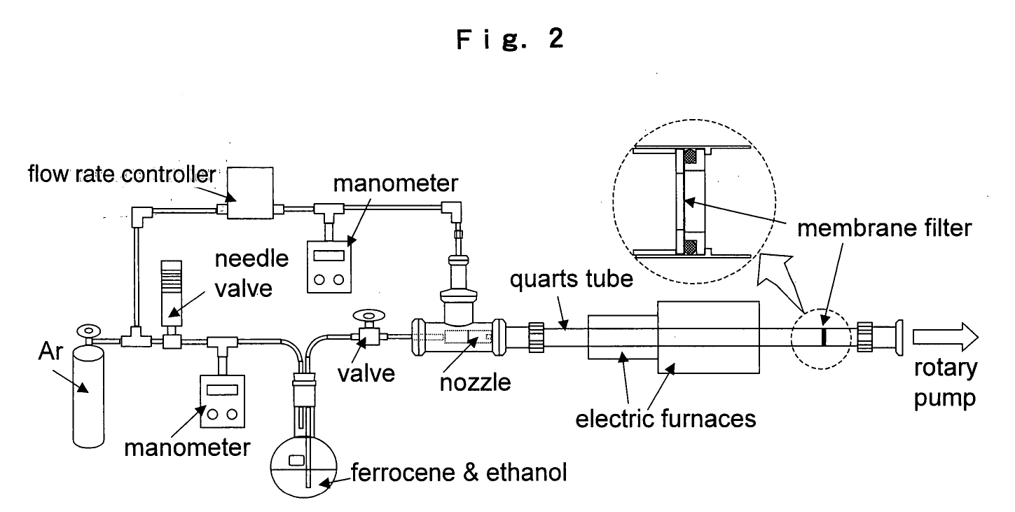

The reaction furnace shown in FIG. 1 was used to produce SWNT by the production process shown in FIG. 2.

A glass tube having a diameter of 24 mm which was allowed to be in a vacuum state by means of a rotary pump was heated by two furnaces. A pre-heating furnace had a length of 20 cm, and a main heating furnace had a length of 30 cm. A 0.2 mass % ferrocene solution in ethanol which was pressurized to a back pressure of 500 Torr by argon gas was sprayed into the glass tube from a nozzle of 0.1 mmθ at a rate of 1 g/minute in the condition that the pre-heating furnace was maintained at 300° C. and that the main heating furnace was maintained at 800, 900 or 1000° C., respectively. The ferrocene-ethanol solution was vaporized in the pre-heating furnace, and the gas pressure became about 200 Torr. When the vaporized gas mixture was heated in the main heating furnace, iron in ferrocene formed an iron cluster, and ethanol was decomposed to produce SWNT. This was cooled in a growing part. Operation in the growing part was carried out in the condition that the reaction tube was exposed to room temperature without heat-insulating the reaction tube. SWNT produced was trapped on a membrane by a membrane filter having a pore diameter of 5 μm, which was provided at a downstream of the growing part. The yields of SWNT at the respective temperatures were about 80% based on the masses of iron and total carbons contained in ferrocene-ethanol in all cases.

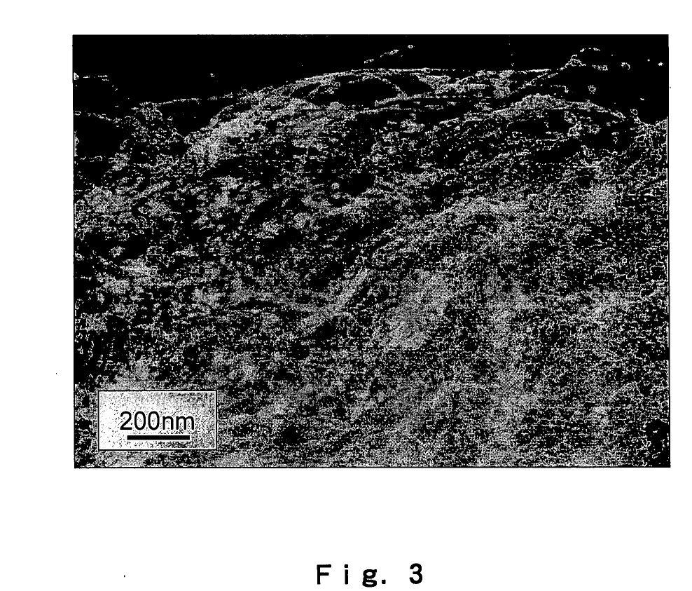

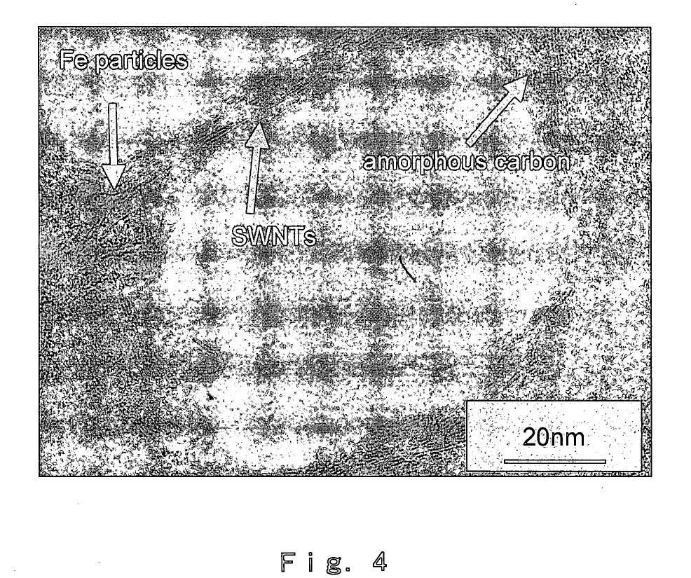

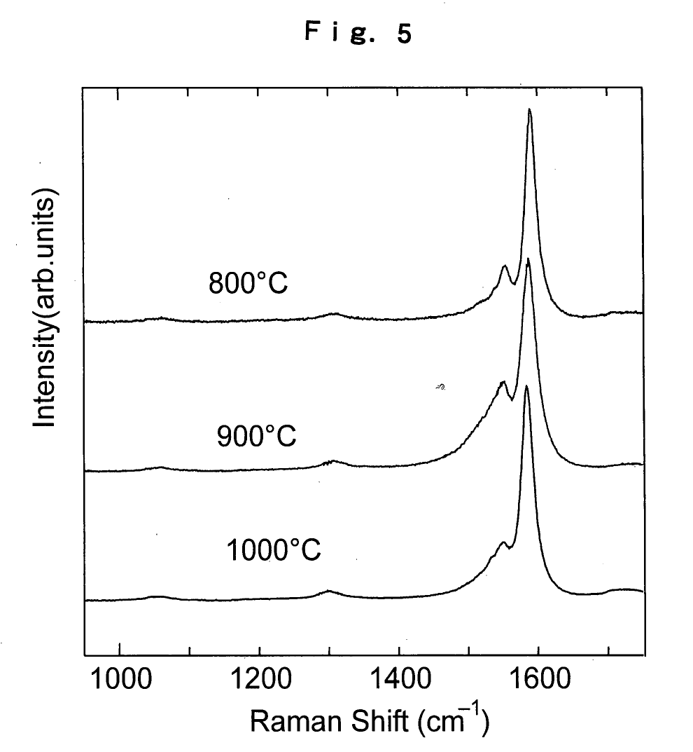

SWNT thus obtained was observed under a scanning electron microscope (SEM) and a transmission electron microscope (TEM), and it was subjected to Raman spectral analysis. The SEM photograph, the TEM photograph and the Raman spectrum at a main heating furnace temperature of 900° C. are shown in FIGS. 3, 4 and 5.

### Comparative Examples 1 to 3

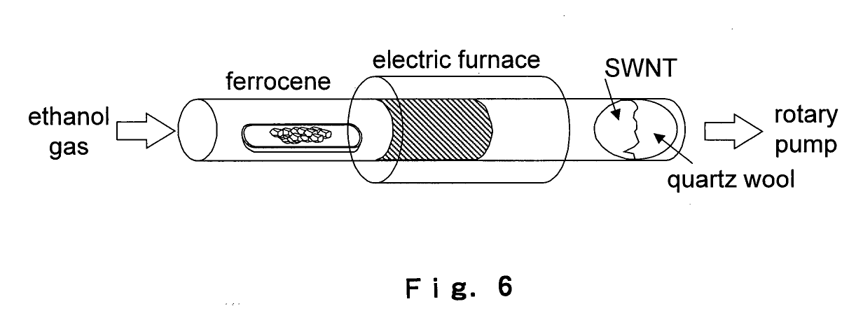

The reaction furnace of a conventional type shown in FIG. 6 was used to produce SWNT by the production process shown in FIG. 2 in the same manner as in Example 1 described above.

A glass tube having a diameter of 24, mm which was allowed to be in a vacuum state by means of a rotary pump was heated by a furnace. A heating furnace had a length of 30 cm. Solid ferrocene as a catalyst was put on a substrate and inserted into a heating part. The equipment was allowed to be in vacuum in the condition that the heating furnace was maintained at 800, 900 or 1000° C., and then ethanol was discharged into the tube at about 10 Torr by a vapor pressure of ethanol at room temperature. Ethanol was decomposed in the reaction furnace to produce SWNT. SWNT produced was trapped on a membrane by a membrane filter having a pore diameter of 5 μm.

The yields of SWNT at the respective temperatures were about 30% based on the masses of iron and total carbons contained in ferrocene-ethanol in all cases.

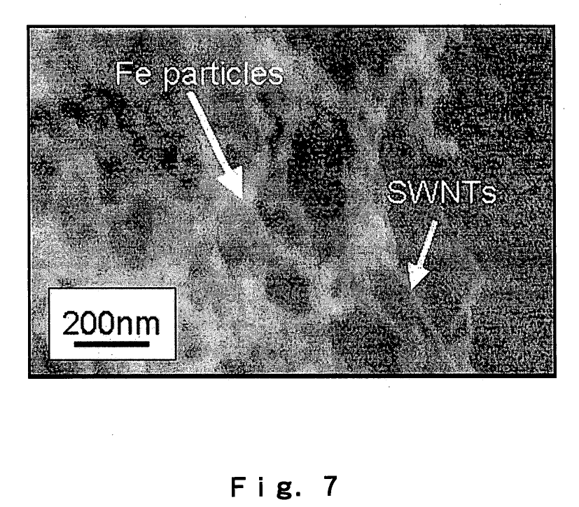

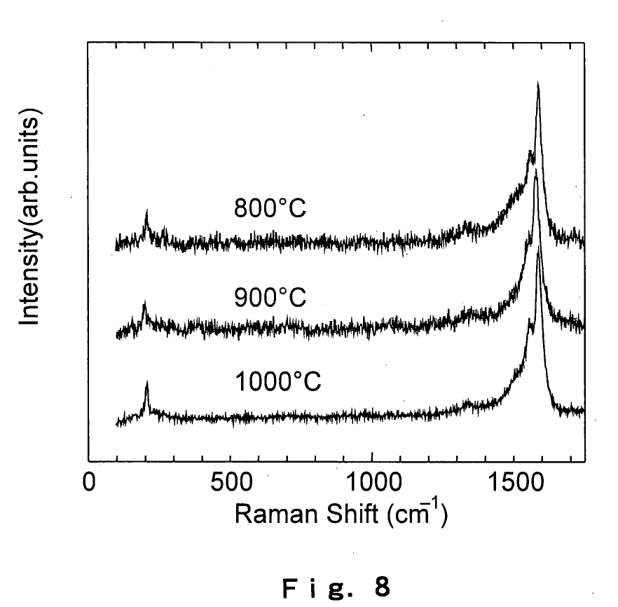

SWNT thus obtained was observed under SEM, and it was subjected to Raman spectral analysis. The SEM photograph and the Raman spectrum at a heating furnace temperature of 900° C. are shown in FIGS. 7 and 8.

In the above reaction system, an amount of SWNT produced in the reaction system is determined according to a collision probability of ethanol, which is the carbon source with the catalyst. Accordingly, when SWNT is produced in the condition that an amount of ethanol fed into the system is small, a large amount of the catalyst has to be fed into the system to raise probability of colliding with each other. However, a large part of the catalyst does not necessarily contribute to decomposition of the carbon source. Accordingly, reduced is the yield which is a proportion of an amount of SWNT produced to the total amount of the carbon source and the catalyst source which are fed into the system.

Further, as an amount of the catalyst to ethanol present in the system is increased, an amount of the catalyst adhered to resulting SWNT as an impurity is increased. Such impurity can be removed by metal removing treatment such as acid treatment, but it causes defects having high reactivity on the surface of SWNT. Accordingly, it is desirable that an amount of the catalyst present in the system is decreased to the utmost to reduce an amount of the catalyst adhered to SWNT to thereby enhance a purity of SWNT.

In the comparative examples described above, ethanol is fed at a pressure of 10 Torr, and therefore an amount of ethanol present in the reaction system is small. Accordingly, as described above, not only the yield is low, but also SWNT of a high purity is not produced.

On the contrary, ethanol is fed at a pressure of 500 Torr in the examples of the present invention, so that a large amount of the carbon source is present in the system. This makes it possible to obtain the satisfactory collision probability without allowing a large amount of the catalyst to be present in the system to an amount of the carbon source and thus to produce SWNT at a high yield. Further, an amount of the catalyst to that of the carbon source is small, and therefore an amount of the catalyst adhered to SWNT can be reduced.

Further, in the examples of the present invention, the solution comprising the carbon source and the catalyst source is sprayed and vaporized, and then the carbon source and the catalyst source are fed into the reaction furnace (main heating part). This makes it possible to allow both to be present in the state of a molecule which is not aggregating to be efficiently decomposed into the catalyst and carbon atoms and makes it possible to further enhance the raw material efficiency. Further, when efficiently synthesizing SWNT, the organic metal compound is heated under an atmosphere of inert gas to decompose and coagulate an organic metal, whereby fine metal particles of about 1 nm are formed. It is desired that the carbon source such as alcohol is then decomposed at further higher temperature with the catalyst to grow a carbon nanotube. If the heating rate is not adequate, the catalyst having a large particle size is produced in a large amount. The catalyst having a large particle size does not effectively contribute to production of the single-walled carbon nanotube, and it remains to adhere to SWNT as an impurity. The pre-heating furnace is provided, and a feed amount of the raw material gas and a flow rate of a carrier gas are changed, whereby the heating rate can be controlled, and an amount of the catalyst which can effectively be used for the reaction can be increased.

In the process of the present invention, a way in which the raw material solution is sprayed and vaporized is employed, and therefore the reaction furnace does not necessarily have to be maintained in a vacuum state. In the examples of the present invention, this makes it possible to feed a large amount of the raw material into the furnace. Further, because the furnace does not have to be maintained in a vacuum state, a pressure in the furnace can be elevated to the level of an atmospheric pressure, so that the reaction system can be constituted at a low cost without using a vacuum vessel and a vacuum pump, which are expensive. This provides the production process of the present invention with a large advantage in industrialization.

### Comparative Example 4

Reported is a production example of SWNT using iron carbonyl as a catalyst metal source and carbon monoxide as a carbon source (P. Nikolaev et al., Chemical Physics Letters, 313, 91 to 97 (1999)).

In the above report example, CO and iron carbonyl which are heated to 200 to 500° C. are fed into a reaction furnace through a first raw material feeding tube, and CO heated to 850° C. is fed into the reaction furnace through a second raw material feeding tube. In this time, Co is decomposed by the action of iron; carbon atoms are obtained; and SWNT is produced. A pressure in the furnace is 1 to 10 atm, and a temperature in the reaction furnace is 800 to 1200° C.

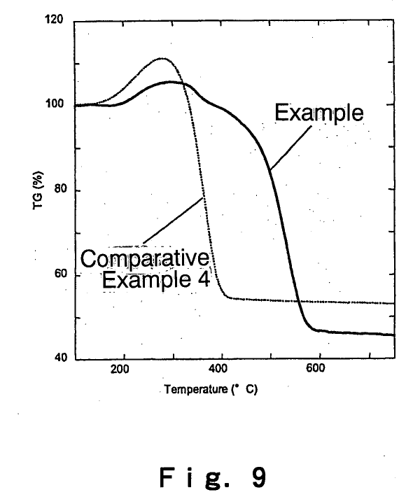

The thermogravimetric analytical data of SWNT produced by the process described above is shown in FIG. 9 together with the thermogravimetric analytical data of SWNT produced in an example of the present invention.

The thermogravimetric analytical data of SWNT produced in the example of the present invention in contrast with the thermogravimetric analytical data of SWNT produced in Comparative Example 4 has three large differences that (1) a burning temperature is high; (2) an amount of the mass increased in the vicinity of 300° C. is small; and (3) an amount of the mass decreased at 400° C. or higher is large.

A difference in the burning temperature reflects difference in an amount of defect in the single-walled carbon nanotube produced and a difference in an amount of the catalyst which is not effectively used in the system. SWNT having a large amount of defects is burned at a low temperature. When catalyst metal is not effectively used in a large amount, the catalyst metal becomes a burning catalyst to induce burning of SWNT, so that SWNT is burned at a low temperature. Accordingly, it can be found that SWNT of the present example having a high burning temperature in the thermogravimetric analysis has less defects and that it is produced making effective use of the catalyst metal.

An increase in the mass at 300° C. or lower shows oxidation of the catalyst metal, and a difference in the increasing amount reflects a difference in an amount of the catalyst metal which is not effectively used. The catalyst metal which is not effectively used is readily oxidized, but the catalyst metal which is effectively used is present in the inside of SWNT, so that it is not oxidized until SWNT is burned. Accordingly, it can be found that in SWNT of the present example in which an increase in the mass is small, an adhered amount of the catalyst metal which is not effectively used is smaller than in the sample of Comparative Example 4. The catalyst metal which is not effectively used forms particles of about 10 nm, and particles of about 10 nm observed in the TEM photograph correspond to the above particles. It can be found that amorphous carbon is scarcely observed from the TEM photograph.

A decrease in the mass at 400° C. or higher reflects burning of the carbon nanotube, and a difference in a mass ratio in the state that the mass is decreased to reach saturation shows an amount of impurities contained in the carbon nanotube. That is, in the process of the present invention, SWNT having a higher purity than that of SWNT produced in Comparative Example 4 can be produced.

According to the process of the present invention, SWNT having an apparently high purity can be produced in a high yield.

### INDUSTRIAL APPLICABILITY

The single-walled carbon nanotube produced according to the present invention is useful as an

1. A process for producing a single-walled carbon nanotube by a vapor deposition technique, comprising:
a step of spraying a solution prepared by dissolving an organic metal compound in an organic solvent into a furnace of a rare gas atmosphere,
a step of vaporizing the organic metal compound and the organic solvent each described above by heating the sprayed solution,
a step of heating and decomposing the vaporized organic metal compound to obtain metal and heating and decomposing the vaporized organic solvent with the metal described above being used as a decomposition catalyst to obtain carbon atoms and
a step of growing a graphene sheet using the carbon atoms obtained.

2. The process for producing a single-walled carbon nanotube as described in claim 1, wherein a pressure in the furnace is controlled to 760 Torr or less.

3. The process for producing a single-walled carbon nanotube as described in claim 2, wherein a pressure in the furnace is controlled to 500 Torr or less.

4. The process for producing a single-walled carbon nanotube as described in claim 1, wherein the organic solvent is alcohol.

5. The process for producing a single-walled carbon nanotube as described in claim 4, wherein the alcohol is ethanol.

6. The process for producing a single-walled carbon nanotube as described in claim 1, wherein the organic metal compound is metallocene.

7. The process for producing a single-walled carbon nanotube as described in claim 6, wherein the metallocene is ferrocene.

8. The process for producing a single-walled carbon nanotube as described in claim 1, wherein the organic metal compound contained in the solution prepared by dissolving the organic metal compound in the organic solvent has a concentration of 0.01 to 1 mass %.

9. The process for producing a single-walled carbon nanotube as described in claim 1, wherein the solution described above which is pressurized by an inert gas having a back pressure of 100 to 1000 Torr is sprayed through a nozzle having an aperture diameter of 0.01 to 1 mm.

10. The process for producing a single-walled carbon nanotube as described in claim 1, wherein a heating temperature for vaporizing the organic solvent and the organic metal compound is 50 to 600° C.

11. The process for producing a single-walled carbon nanotube as described in claim 10, wherein a heating temperature for vaporizing the organic solvent and the organic metal compound is 100 to 400° C.

12. The process for producing a single-walled carbon nanotube as described in claim 10, wherein a heating temperature for heating and decomposing the organic solvent and the organic metal compound is 550 to 1000° C.

13. The process for producing a single-walled carbon nanotube as described in claim 11, wherein a heating temperature for heating and decomposing the organic solvent and the organic metal compound is 700 to 1000° C.

14. The process for producing a single-walled carbon nanotube as described in claim 12, wherein a temperature for growing the graphene sheet is lower than a temperature of heating the organic solvent.

15. The process for producing a single-walled carbon nanotube as described in claim 13, wherein a temperature for growing the grapheme sheet is lower than a temperature of heating the organic solvent.

16. The process for producing a single-walled carbon nanotube as described in claim 9, wherein the inert gas is argon or helium.

17. The process for producing a single-walled carbon nanotube as described in claim 9, wherein 5 mass % or less of hydrogen gas is mixed with the inert gas.

18. The process for producing a single-walled carbon nanotube as described in claim 1, wherein the single-walled carbon nanotube comprising the grown graphene sheet is collected by a membrane filter.

19. Equipment for producing a single-walled carbon nanotube by a vapor deposit technique, comprising:
a nozzle for spraying a solution prepared by dissolving an organic metal compound in an organic solvent by pressurizing with an inert gas having a prescribed back pressure,
a pre-heating part for vaporizing the organic metal compound and the organic solvent each described above by heating the sprayed solution,
a main heating and decomposing the organic metal compound vaporized in the pre-heating part and heating and decomposing the organic solvent vaporized in the pre-heating part with the metal obtained by heating and decomposing the organic metal compound being used as a catalyst,
a growing part for growing a graphene sheet using carbon atoms obtained by heating and decomposing the solvent described above in the main heating part,
a first controlling means for heating and maintaining a temperature of the furnace in the pre-heating part described above at 50 to 600° C.,
a second controlling means for heating and maintaining a temperature of the furnace in the main heating part described above at 550 to 1000° C. and
a third controlling means for maintaining the pre-heating part, the main heating part and the growing part in a rare gas atmosphere.
